(19) United States
(12) Patent Application Publication
(10) Pub. No.: US 2008/0064358 A1
(43) Pub. Date: Mar. 13, 2008

(54) SEMICONDUCTOR DEVICE AND METHOD FOR MAKING THE SAME

(75) Inventors: Yoshitomo Sagae, Yokohama-shi (JP); Fumio Sasaki, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/853,423

(22) Filed: Sep. 11, 2007

(30) Foreign Application Priority Data
Sep. 12, 2006 (JP) 2006-246688

(51) Int. Cl. H01L 27/12; H01L 21/84; H04B 1/28

(52) U.S. Cl. 455/333; 257/347; 438/151; 257/E27.111; 257/E21.703

(57) ABSTRACT

A semiconductor device includes: an SOI substrate with a silicon oxide layer 123 formed on a silicon substrate 122 and a semiconductor layer formed thereon; and a MOSFET formed within the semiconductor layer, wherein a region of the silicon substrate 122 through the silicon oxide layer 123 is removed by etching, which corresponds to a region of the semiconductor layer where the MOSFET is formed.

### CROSS REFERENCE TO RELATED APPLICATIONS

This application is based on and claims the benefit of priority from prior Japanese Patent Application No. 2006-246688, filed on Sep. 12, 2006, the entire contents of which are incorporated herein by reference.

### BACKGROUND OF THE INVENTION

1. Field of the Invention

The present invention relates to a semiconductor device and a method for making the same, and particularly, to a high frequency enabled semiconductor device and a method for making the same.

2. Description of the Related Art

Recently, with the proliferation of wireless communication devices such as portable phones and wireless LANs, and with the development of information devices or systems due to the multi-channelization of satellite broadcasting, there is increasing demands for a GHz-band microwave enabled semiconductor switch for use in an RF transceiver of these devices.

The semiconductor switch includes a compound semiconductor switch with a GaAs Field Effect Transistor (FET), which may provide superior high frequency characteristics and high isolation between signal paths.

However, since the GaAs substrate is more costly than the Si substrate and for now there has been only modest progress in providing larger diameter of the GaAs substrate, it is difficult to reduce the cost of electric devices with such GaAs.

In this respect, the relevant industry has considered the development of a high frequency MOSFET with a Si substrate. Specifically, as disclosed in the publication, J. Bonkowski, et.al., “Integration of Triple-Band GSM Antenna Switch Module Using SOI CMOS”, IEEE RFIC Symp. Dig., 2004, pp.511-514, which is incorporated herein by reference, SOI (silicon On Insulator) substrates enable reduction of parasitic capacitance and improvement in characteristics.

In addition, as disclosed in the document, Mei-Chao Yeh, et.al., “A Millimeter-Wave Wideband SPDT Switch with Traveling-Weve Concept Using 0.13-μm CMOS Process”, IEEE MTT-S International Microwave Symp., 2005, pp.53-57, which is also incorporated herein by reference, SOS (silicon On Sapphire) substrates also enables such reduction and improvement.

In this case, with the SOS substrate, it is possible to reduce parasitic capacitance because of the use of a Sapphire substrate with high insulation. However, it is difficult to provide the epitaxial growth of single crystal Si due to the difference of crystal structure and lattice constant between Sapphire and Si. This tends to cause a lattice defect in forming a Si layer by means of epitaxial growth, which could result in reduction of yields. Further, the Sapphire substrate has problems that require too much cost to reduce the cost of devices for manufacture, etc.

In contrast, the SOI substrate has no such problems. There has been disclosed an invention for a specific device with such an SOI substrate, as in Japanese Patent Laying-open publication No. 2000-327553, which is herein incorporated by reference.

### SUMMARY OF THE INVENTION

In one aspect of the present invention, a semiconductor device comprises: an SOI substrate with a semiconductor substrate, an insulating layer formed on the semiconductor substrate, and a semiconductor layer formed on the insulating layer, wherein a region of the semiconductor substrate on an rear surface of the SOI substrate is removed, the region corresponding to a region of the semiconductor layer where a MOSFET is to be formed; and a MOSFET formed within the semiconductor layer on a surface of the SOI substrate.

In another aspect of the present invention, a method for making a semiconductor device including a MOSFET on an SOI substrate comprising a semiconductor substrate, an insulating layer formed on the semiconductor substrate, and a semiconductor layer formed on the insulating layer comprises: forming a MOSFET within the semiconductor layer on a surface of the SOI substrate; forming a thick film electrode within a predetermined region on an electrode of the MOSFET; adhering the thick film electrode to a supporting substrate; etching the semiconductor substrate on an rear surface of the SOI substrate; and removing the supporting substrate.

### BRIEF DESCRIPTION OF THE DRAWINGS

FIG. 1 is a circuit diagram of a shunt-type SPDT switch in accordance with a first embodiment of the present invention;

FIG. 2 is a plan view of a semiconductor device of the first embodiment of the present invention;

FIG. 3 is a sectional view taken in the line 3A-3B of FIG. 2;

FIG. 4 is a sectional view taken in the line 4A-4B of FIG. 2;

FIG. 5 is a plan view of a semiconductor device in accordance with a second embodiment of the present invention;

FIG. 6 is a sectional view taken in the line 6A-6B of FIG. 5;

FIG. 7 illustrates a method for making a semiconductor device in accordance with the first embodiment of the present invention;

FIG. 8 illustrates a method for making a semiconductor device in accordance with the first embodiment of the present invention;

FIG. 9 illustrates a method for making a semiconductor device in accordance with the first embodiment of the present invention;

FIG. 10 illustrates a method for making a semiconductor device in accordance with the first embodiment of the present invention;

FIG. 11 illustrates a method for making a semiconductor device in accordance with the first embodiment of the present invention;

FIG. 12 illustrates a method for making a semiconductor device in accordance with the second embodiment of the present invention; and

FIG. 13 illustrates a method for making a semiconductor device in accordance with the second embodiment of the present invention.

### DETAILED DESCRIPTION OF THE INVENTION

The present invention relates to a high frequency circuit including a MOSFET that is formed on an SOI substrate. When the high frequency circuit including a MOSFET is formed on the SOI substrate, Si has conductivity in a silicon substrate through a silicon oxide layer of the SOI substrate. As such, if the MOSFET is driven at a high frequency around 1 GHz, a capacitive coupling occurs between ohmic electrodes of the MOSFET (a source electrode and a drain electrode) and the silicon substrate. This results in an increase in insertion loss, inducing a problem of the degradation of isolation (cutoff characteristics). This phenomenon will prominently occur not only for the drive frequency being driven at the high frequency around 1 GHz, but also for being driven at a frequency as high as about 800 MHz. One or more of these problems are solved by those skilled in the art with any one or combination of, or optimization of, embodiments of the present invention described below.

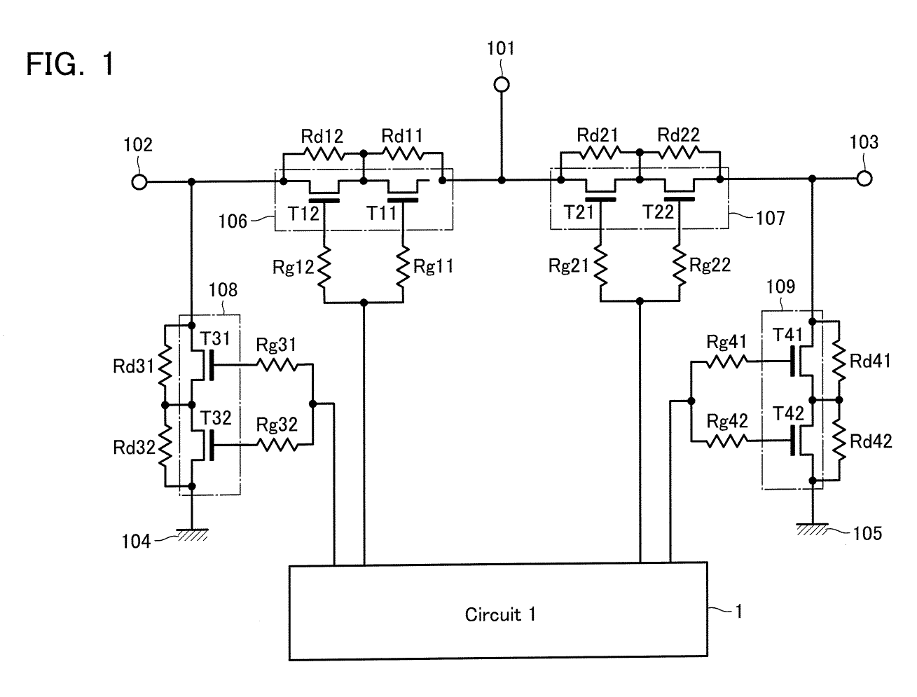

A first embodiment of the present invention is now described with reference to the accompanying drawings. The present invention, however, is not limited to this embodiment. FIG. 1 is a circuit diagram of a shunt-type SPDT switch circuit, which is one of high frequency switching circuits in accordance with the first embodiment.

As illustrated in FIG. 1, the shunt-type SPDT switch circuit in accordance with the first embodiment of the present invention includes a first through-MOSFET circuit 106 between an antenna terminal 101 and a first RF terminal 102. The first through-MOSFET circuit 106 comprises two MOSFETs (T11, T12). Each gate electrode of these two MOSFETs (T11, T12) is connected to a control circuit 1 via each gate additional resistance (Rg11, Rg12). The control circuit 1 adjusts each gate potential of these two MOSFETs (T11, T12), thereby controlling conduction and cutoff of an RF signal through and from the first through-MOSFET circuit 106. In addition, between each source electrode and drain electrode of these two MOSFETs (T11, T12), additional resistances (Rd11, Rd12) are connected in parallel to each source and drain of the MOSFETs (T11, T12) respectively, in order to maintain a constant potential difference between each source and drain.

The shunt-type SPDT switch circuit in accordance with the first embodiment of the present invention also includes a second through-MOSFET circuit 107 between the antenna terminal 101 and a second RF terminal 103. The second through-MOSFET circuit 107 comprises two MOSFETs (T21, T22). Each gate electrode of these two MOSFETs (T21, T22) is connected to the control circuit 1 via each gate additional resistance (Rg21, Rg22). The control circuit 1 adjusts each gate potential of these two MOSFETs (T21, T22), thereby controlling conduction and cutoff of an RF signal through and from the second through-MOSFET circuit 107. In addition, between each source electrode and drain electrode of these two MOSFETs (T21, T22), additional resistances (Rd21, Rd22) are connected in parallel to each source and drain of the MOSFETs (T21, T22) respectively, in order to maintain a constant potential difference between each source and drain.

The shunt-type SPDT switch circuit in accordance with the first embodiment of the present invention further includes a first shunt-MOSFET circuit 108 between the first RF terminal 102 and a GND terminal 104. The first shunt-MOSFET circuit 108 comprises two MOSFETs (T31, T32). Each gate electrode of these two MOSFETs (T31, T32) is connected to the control circuit 1 via each gate additional resistance (Rg31, Rg32). The control circuit 1 adjusts each gate potential of these two MOSFETs (T31, T32), thereby controlling conduction and cutoff of an RF signal through and from the first shunt-MOSFET circuit 108. Further, between each source electrode and drain electrode of these two MOSFETs (T31, T32), additional resistances (Rd31, Rd32) are connected in parallel to each source and drain of the MOSFETs (T31, T32) respectively, in order to maintain a constant potential difference between each source and drain.

The shunt-type SPDT switch circuit in accordance with the first embodiment of the further includes a second shunt-MOSFET circuit 109 between the second RF terminal 103 and a GND terminal 105. The second shunt-MOSFET circuit 109 includes two MOSFETs (T41, T42). Each gate electrode of these two MOSFETs (T41, T42), which is connected to the control circuit 1 via each gate additional resistance (Rg41, Rg42), controls conduction and cutoff of an RF signal with each gate potential. In addition, source/drain additional resistances (Rd41, Rd42) are connected in parallel between each source electrode and drain electrode, in order to maintain a constant bias for each source and drain.

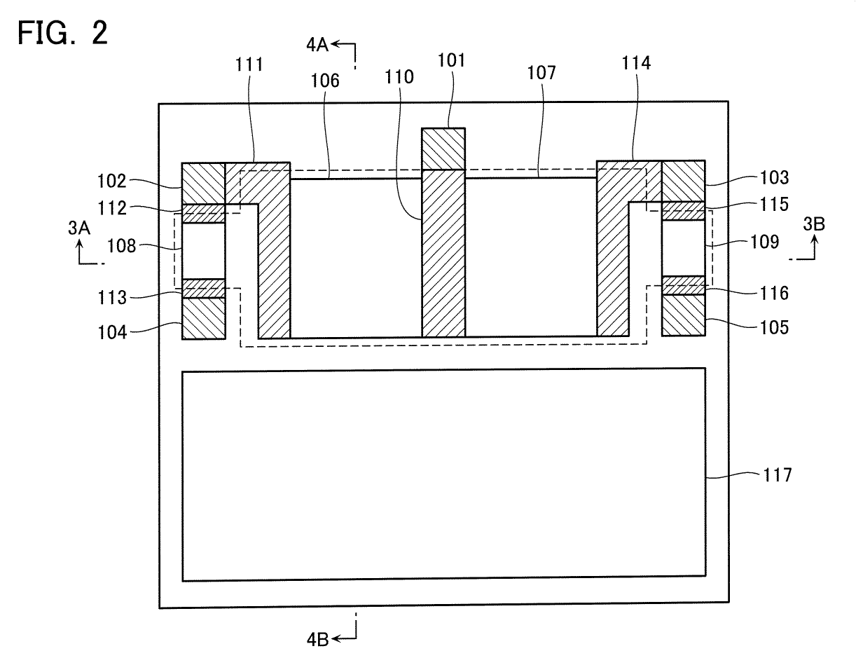

Referring now to FIG. 2, the first embodiment of the present invention is described below. FIG. 2 is a plan view of an SOI substrate, illustrating the circuit arrangement of the shunt-type SPDT switch circuit illustrated in FIG. 1.

The antenna terminal 101 is connected to the first through-MOSFET circuit 106 and the second through-MOSFET circuit 107 through a metal wire 110. The first through-MOSFET circuit 106 is connected to the first RF terminal 102 through a metal wire 111. The first RF terminal 102 is connected to the first shunt-MOSFET circuit 108 through a metal wire 112. The first shunt-MOSFET circuit 108 is connected to the GND terminal 104 through a metal wire 113.

The second through-MOSFET circuit 107 is connected to the second RF terminal 103 through a metal wire 114. The second RF terminal 103 is connected to the second shunt-MOSFET circuit 109 through a metal wire 115. The second shunt-MOSFET circuit 109 is connected to the GND terminal 105 through a metal wire 116. In one embodiment of the present invention, a logic circuit 117 is formed adjacent to a region where the shunt-type SPDT switch circuit is formed. The present invention, however, is not limited to the circuit arrangement as illustrated in FIG. 2.

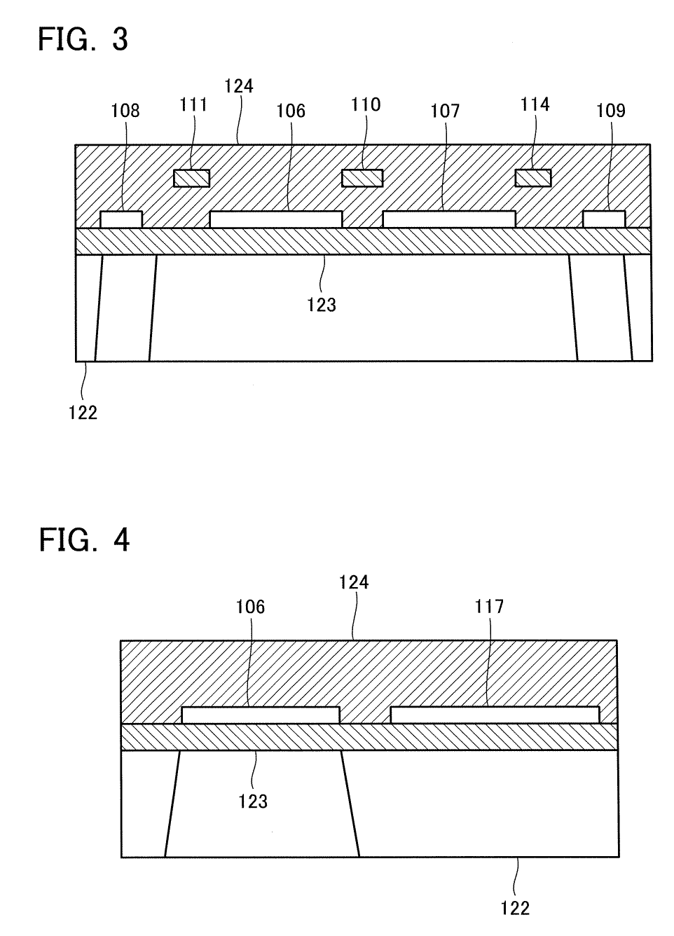

Description is now made to a cross sectional structure of the SOI substrate where the shunt-type SPDT switch circuit in accordance with the first embodiment of the present invention is formed. FIG. 3 is a sectional view taken in the line 3A-3B of FIG. 2; and FIG. 4 is a sectional view taken in the line 4A-4B of FIG. 2. In the first embodiment of the present invention, a MOSFET is formed on an SOI substrate. The SOI substrate involves: an insulating layer such as a silicon oxide layer 123 formed on an n-type or p-type silicon substrate 122; and an n-type or p-type silicon semiconductor layer epitaxially grown thereon. The MOSFET is formed within the semiconductor layer. The metal wires 111, 110 and 114 are formed on top of the MOSFET through an interlayer dielectric film, while an insulating layer 124 such as a silicon oxide film is deposited on the surfaces of these metal wires 111, 110 and 114.

In the first embodiment of the present invention, as illustrated in FIG. 3 and FIG. 4, a region of the silicon substrate 122 through a silicon oxide layer 123 is removed by etching, which corresponds to a region of the semiconductor layer where the first through-MOSFET circuit 106, the second through-MOSFET circuit 107, the first shunt-MOSFET circuit 108, and the second shunt-MOSFET circuit 109 are formed (i.e., a region of the silicon substrate 122 on an rear surface of the SOI substrate, surrounded by dashed lines in FIG. 2, is removed) Specifically, using a mask formed by a photolithography technique, the silicon substrate 122 is selectively removed by anisotropic etching, such as RIE, to expose the silicon oxide layer 123 of the SOI substrate. The silicon oxide film 123 has preferably a thickness of at least 0.2 μm or more in order to prevent any effect from over etching on the MOSFET.

By removing the region of the silicon substrate 122 through a silicon oxide layer 123, which corresponds to a region of the semiconductor layer where the first through-MOSFET circuit 106, the second through-MOSFET circuit 107, the first shunt-MOSFET circuit 108, and the second shunt-MOSFET circuit 109 are formed, there will be no such silicon substrate 122 with conductivity for a capacitive coupling. This results in no increase of insertion loss or no degradation of isolation (cutoff characteristics) when the MOSFETs configuring these circuits are driven at a high frequency. In other wards, when the shunt-type SPDT switch circuit in accordance with the first embodiment of the present invention is driven at a high frequency, not less than 800 MHz, as described above, the insertion loss will not increase and the isolation (cutoff characteristics) will not degrade.

In this respect, the gate length of MOSFET for use in the first through-MOSFET circuit 106, the second through-MOSFET circuit 107, the first shunt-MOSFET circuit 108 and the second shunt-MOSFET circuit 109 has preferably a gate length ranging from about 0.2 μm to about 0.6 μm (0.2 μm, 0.3 μm, 0.4 μm, 0.5 μm, and 0.6 μm, as well as between any two of these), it is not so limited.

In addition, with respect to the region of the silicon substrate 122 being removed, since only a region where the parasitic capacitance could affect the high frequency characteristics needs to be removed (i.e., at least the region of the silicon substrate 122 through a silicon oxide layer 123 needs to be removed, which corresponds to a region of the semiconductor layer where the first through-MOSFET circuit 106, the second through-MOSFET circuit 107, the first shunt-MOSFET circuit 108, and the second shunt-MOSFET circuit 109 are formed), a region of the silicon substrate 122 does not need to be removed, which corresponds to a region of the semiconductor layer where the logic circuit 117 (FIG. 2) is formed.

For example, the SOI substrate used in the first embodiment is formed by, including, but not limited to, depositing a silicon oxide layer 123 with a thickness of about 1-2 μm on a silicon substrate 122 with a thickness of about 725 μm and forming a semiconductor layer thereon. A first through-MOSFET circuit 106, a second through-MOSFET circuit 107, a first shunt-MOSFET circuit 108, and a second shunt-MOSFET circuit 109 are formed within the semiconductor layer. Then, the silicon substrate 122 on an rear surface of the SOI substrate is polished to a thickness between about 50 μm to about 300 μm (50 μm, 100 μm, 150 μm, 200 μm, 250 μm, and 300 μm, as well as between any two of these).

Thereafter, the region of the silicon substrate 122 through a silicon oxide layer 123, which corresponds to a region of the semiconductor layer where the first through-MOSFET circuit 106, the second through-MOSFET circuit 107, the first shunt-MOSFET circuit 108, and the second shunt-MOSFET circuit 109 are formed, is etched by anisotropic etching, such as RIE, to expose the surface of the silicon oxide layer 123.

Referring again to the drawings, a second embodiment of the present invention is described below. The circuit configuration is same as the first embodiment illustrated in FIG. 1, and description of which will be omitted. In addition, the circuit arrangement on the SOI substrate is also same as the first embodiment illustrated in FIG. 2, and description of which will be omitted. A semiconductor device in accordance with the second embodiment of the present invention is different from the first embodiment in its cross sectional structure.

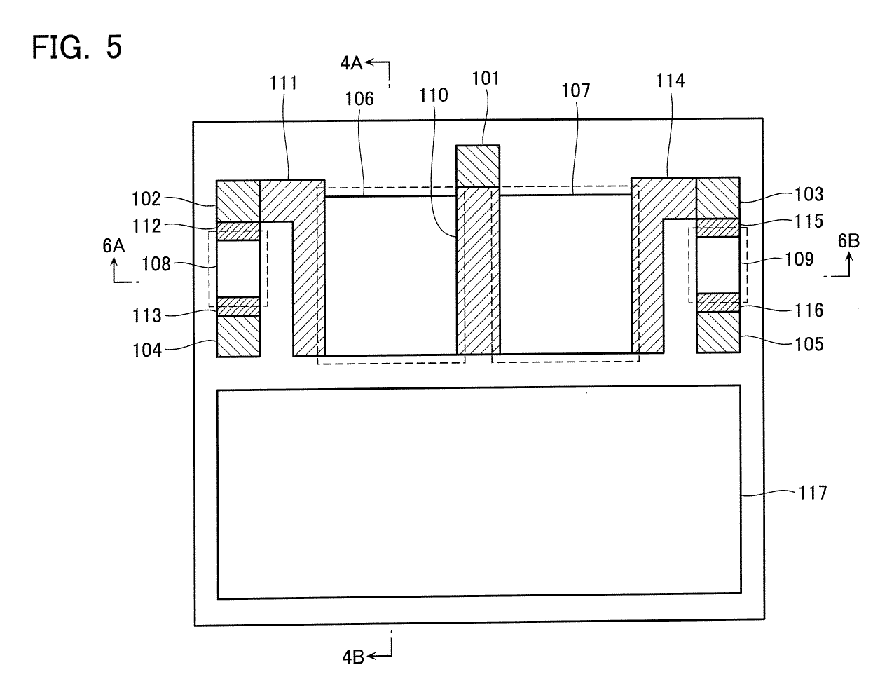

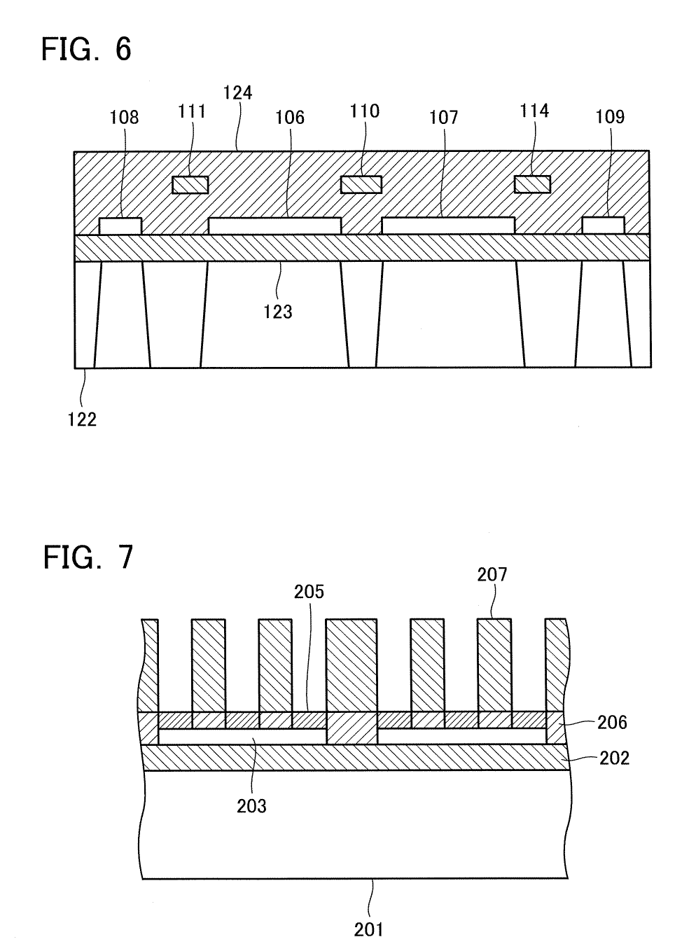

FIG. 5 is a plan view of the semiconductor device in accordance with the second embodiment of the present invention. FIG. 6 is a sectional view of the semiconductor device taken in the line 6A-6B in accordance with the second embodiment. Here, the sectional view taken in the line 4A-4B is same as FIG. 4, and description of which will be omitted. For the semiconductor device in accordance with the second embodiment, only individual regions of the silicon substrate 122 through the silicon oxide layer 123 are removed, which correspond to individual device regions of the semiconductor layer where the first through-MOSFET circuit 106, the second through-MOSFET circuit 107, the first shunt-MOSFET circuit 108, and the second shunt-MOSFET circuit 109 are formed, respectively, (i.e., only regions of the silicon substrate 122 are removed, which correspond to the regions of the semiconductor layer, surrounded by dashed lines in FIG. 5, where MOSFET circuits are formed). The second embodiment has a larger amount of silicon substrate 122 as compared to the sectional view of the first embodiment shown in FIG. 3.

In this way, such limited removal of the silicon substrate 122 reduces the amount of anisotropic etching, such as RIE, as compared to the first embodiment. Consequently, the semiconductor device of the second embodiment has higher mechanical strength of the semiconductor device after etching.

Referring again to the drawings, a method for making a semiconductor device in accordance with the present invention is described below. The method for making a semiconductor device is not limited to the following method. FIGS. 7-11 illustrate a first embodiment of the method for making a semiconductor device in accordance with the present invention.

Firstly, as illustrated in FIG. 7, a silicon oxide film 202 is formed on a silicon substrate 201, on which an epitaxially grown SOI substrate is further prepared by a silicon semiconductor layer to form a MOSFET circuit 203 within the silicon semiconductor layer by ion implantation. Thereafter, an interlayer dielectric film 206 is formed and a metal electrode 205 is also formed by a photolithography and etching process.

Then, a photoresist is applied to the surface of the metal electrode 205 being formed. As a resist used herein, a very thick film resist (SU-8, manufactured by Kayaku MicroChem Corporation) is employed, which is uniformly applied in a thickness of not less than about 50 μm. In this case, the thickness of the resist is not so limited. Then, a mask 207 with an aperture is formed by a photolithography technique on a region where the metal electrode 205 is formed.

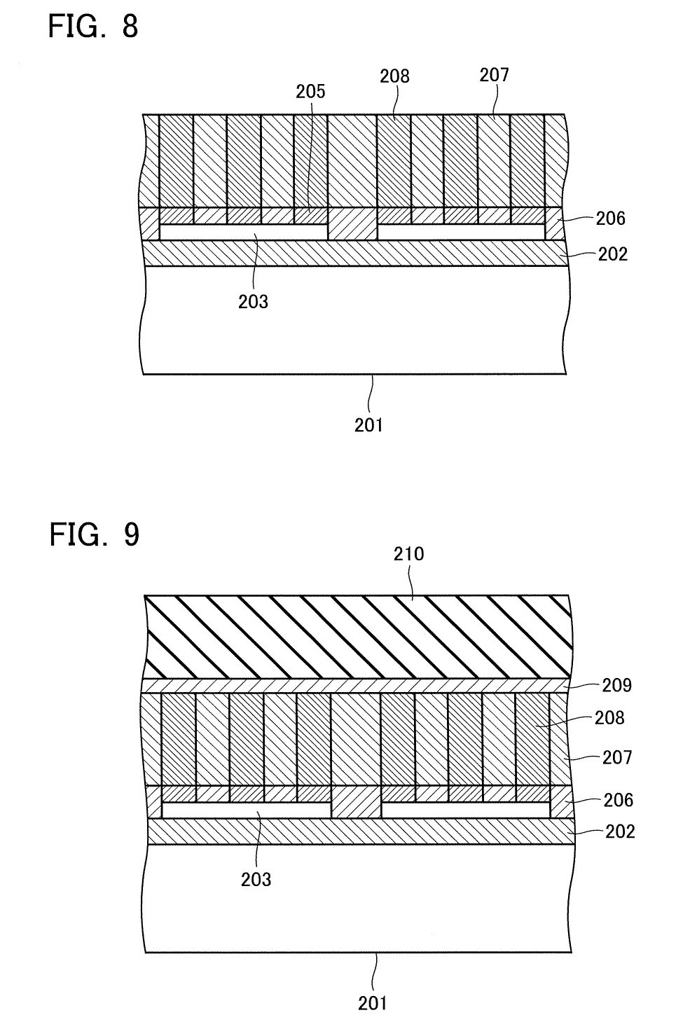

Then, as illustrated in FIG. 8, the mask 207 is used to deposit a thick-film metal electrode 208, e.g., by electroless plating. The thick-film metal electrode 208 is deposited to the thickness of the mask 207. Thus, the thickness of the thick-film metal electrode 208 to be formed is not less than 50 μm. In this case, although the mask 207 and the thick-film metal electrode 208 preferably have a thickness of not less than 50 μm, they are not so limited.

Then, as illustrated in FIG. 9, a supporting substrate, e.g., a quartz substrate 210 is adhered on the side where the mask 207 and the thick-film metal electrode 208 are formed via an adhesive tape, e.g., a foam tape 209.

Then, a photoresist is applied to the silicon substrate 201 in a surface opposite to the surface to which the quartz substrate 210 is adhered, and a mask (not shown) with an aperture is formed only in a region of the silicon substrate 201 using a photolithography technique, which corresponds to a region of the semiconductor layer where the MOSFET circuit 203 is formed.

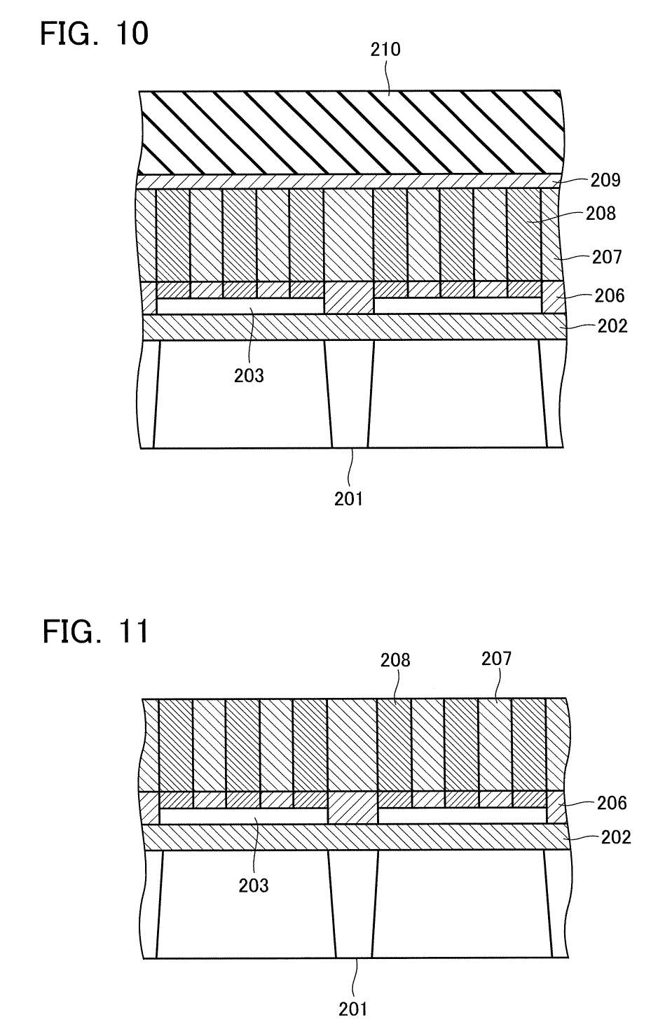

Then, as illustrated in FIG. 10, that mask is used to perform anisotropic etching by RIE (Reactive Ion Etching) using a gas such as CF₄, thereby removing the silicon substrate 201 of the mask aperture to expose the silicon oxide film 202. Then, for example, an organic solvent is used to remove the mask and to divide it in chips by dicing etc., as needed.

Finally, as illustrated in FIG. 11, the foam tape 209 is foamed by heating to a predetermined temperature to separate the quartz substrate 210.

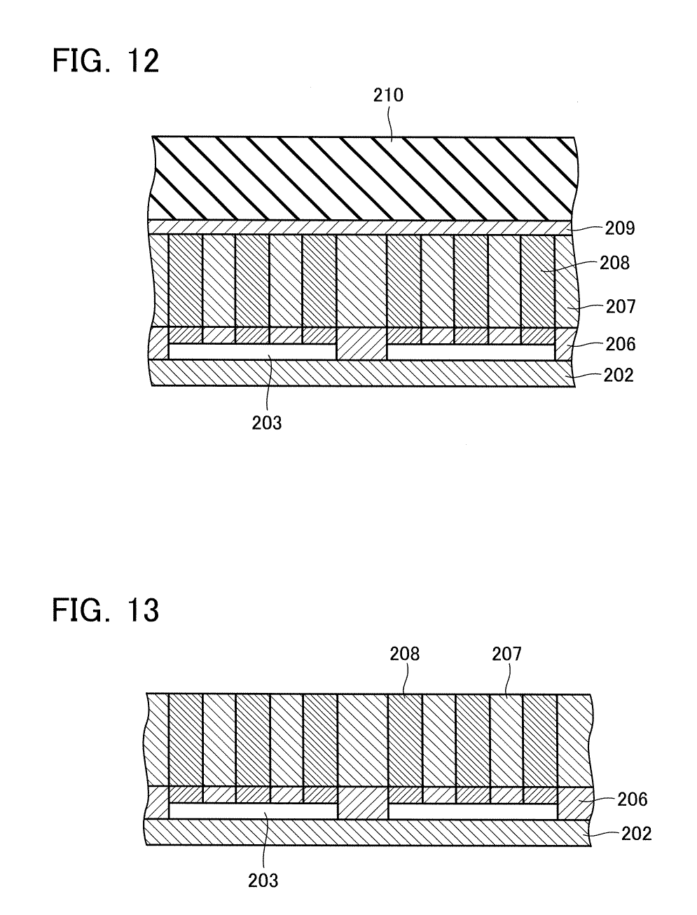

Still referring to the drawings, a second embodiment of the method for making a semiconductor device in accordance with the present invention is described below. FIG. 12 and FIG. 13 illustrate the second embodiment of the method for making a semiconductor device in accordance with the present invention.

The steps illustrated in FIGS. 7-9 are same as the first embodiment, and description thereof will be omitted. In FIG. 9, adherence of the quartz substrate 210 is first performed, and then is performed wet etching with, e.g., a KOH (potassium hydroxide) solution. This removes, as illustrated in FIG. 12, the silicon substrate 201 on an rear surface of the SOI substrate in its entirety. In this case, the wet etchant is not limited to potassium hydroxide.

Then, as illustrated in FIG. 13, the foam tape 209 is foamed by heating to a predetermined temperature to separate the quartz substrate 210.

### EXAMPLES

The semiconductor device in accordance with examples of the present invention will now be described with respect to the evaluation test conducted for the insertion loss and isolation (cutoff characteristics) performance.

### Example 1

Example 1 is based on the shunt-type SPDT switch circuit in accordance with the first embodiment of the present invention. Specifically, an SOI substrate was used, wherein a silicon oxide layer 123 with a thickness of about 2 μm was formed on a silicon substrate 122 with a thickness of about 725 μm, and a silicon semiconductor layer with a thickness of 70 μm was epitaxially grown on the silicon oxide layer 123. Here, the specific resistance of the silicon substrate 122 was 1000 Ωcm.

A shunt-type SPDT switch circuit including MOSFET was formed within the silicon semiconductor layer of the SOI substrate. The MOSFET, a high frequency switching device, comprised an NMOS transistor. The NMOS transistor had the following specification: the Vth (threshold voltage)=about 0.5V; the Lg (gate length)=about 0.25 μm; the Ron (source/drain on resistance)=about 1.5 Ωmm; the Coff (source/drain capacitance)=about 0.28 pF/mm. The Wg (gate width) of NMOS transistors (T11, T12, T21 and T22) which configured the through-MOSFET circuits 106 and 107 was about 0.6 mm. The Wg (gate width) of NMOS transistors (T31, T32, T41 and T42) which configure the shunt-MOSFET circuits 108 and 109 was about 0.2 mm. The additional resistance at each gate of each NMOS transistor (Rg11, Rg12, Rg21, Rg22, Rg31, Rg32, Rg41 and Rg42) was about 10 kΩ. The additional resistance at each source/drain of each NMOS transistor (Rd11, Rd12, Rd21, Rd22, Rd31, Rd32, Rd41 and Rd42) was about 10 kΩ.

The shunt-type SPDT switch circuit so configured was formed within the semiconductor layer on a surface of the SOI substrate. Then, the silicon substrate 122 on an rear surface of the SOI substrate was polished to a thickness of 100 μm. Then, a region of the silicon substrate 122 through the silicon oxide layer 123 was subject to anisotropic etching such as RIE, which corresponded to the region of the semiconductor layer where the through-MOSFET circuits 106 and 107 as well as the shunt-MOSFET circuits 108 and 109 were formed. By this etching, a whole region of the silicon substrate 122 was removed, which corresponded to the region of the semiconductor layer where the circuit was formed.

In the shunt-type SPDT switch circuit of Example 1, it was found that, at a frequency of 1.9 GHz, the insertion loss was 0.63 dB and the isolation (cutoff characteristics) was 42.88 dB, respectively.

### Comparative Example 1

As Comparative Example 1, an evaluation test was conducted, wherein the same shunt-type SPDT switch circuit as example 1 was formed on the same SOI substrate as example 1, and no etching was performed on the silicon substrate 122.

In the shunt-type SPDT switch circuit of Comparative Example 1, it was found that, at a frequency of 1.9 GHz, the insertion loss was 0.64 dB and the isolation (cutoff characteristics) was 37.36 dB, respectively.

From the above evaluation test for the insertion loss and isolation (cutoff characteristics), Example 1 in accordance with the present invention was found to yield better results than Comparative Example 1. In particular, a significant improvement was found in the isolation (cutoff characteristics).

Although particular embodiments of the present invention have been described above, it will be apparent to those skilled in the art that various additions, modifications, or replacements can be made without departing from the spirit and aspects of the present invention as defined in the claims. For example, although the present invention has been described in detail in the context of the semiconductor device where the shunt-type SPDT switch circuit was formed, the semiconductor device of the present invention is not intended to be limited to the details given herein, and so may be applied to other switching circuits.

What is claimed is:

1. A semiconductor device comprising:
an SOI substrate comprising a semiconductor substrate, an insulating layer formed on the semiconductor substrate, and a semiconductor layer formed on the insulating layer, wherein a region of the semiconductor substrate on an rear surface of the SOI substrate is removed, the region corresponding to a region of the semiconductor layer where a MOSFET is to be formed; and
a MOSFET formed within the semiconductor layer on a surface of the SOI substrate.

2. The semiconductor device according to claim 1, wherein the insulating layer comprises a silicon oxide layer, and the silicon oxide layer has a thickness of not less than 0.2 μm.

3. The semiconductor device according to claim 1, wherein the MOSFET configures a shunt-type SPDT switch circuit, and the shunt-type SPDT switch circuit comprises a first through-MOSFET circuit connected between an antenna terminal and a first RF terminal, a second through-MOSFET circuit connected between the antenna terminal and a second RF terminal, a first shunt-MOSFET circuit connected between the first RF terminal and a ground terminal, and a second shunt-MOSFET circuit connected between the second RF terminal and the ground terminal.

4. The semiconductor device according to claim 3, wherein a region of the semiconductor substrate on an rear surface of the SOI substrate is removed where the first through-MOSFET circuit, the second through-MOSFET circuit, the first shunt-MOSFET circuit, and the second shunt-MOSFET circuit are formed.

5. The semiconductor device according to claim 4, wherein the insulating layer comprises a silicon oxide layer, and the silicon oxide layer has a thickness of not less than 0.2 μm.

6. A method for making a semiconductor device including a MOSFET on an SOI substrate comprising a semiconductor substrate, an insulating layer formed on the semiconductor substrate, and a semiconductor layer formed on the insulating layer, the method comprising:
forming a MOSFET within the semiconductor layer on a surface of the SOI substrate;
forming a thick film electrode on an electrode of the MOSFET;
adhering the thick film electrode to a supporting substrate;
etching the semiconductor substrate on an rear surface of the SOI substrate; and
removing the supporting substrate.

7. The method for making the semiconductor device according to claim 6, wherein the forming the thick film electrode further comprises: forming a mask with an aperture on the electrode of the MOSFET using a photolithography technique; and depositing a metal film within the aperture using the mask.

8. The method for making the semiconductor device according to claim 7, wherein the metal film has a thickness of not less than 50 μm.

9. The method for making the semiconductor device according to claim 6, wherein the supporting substrate is adhered to the thick film electrode via a foam tape.

10. The method for making the semiconductor device according to claim 6, wherein the etching the semiconductor substrate further comprises: forming a mask with an aperture on a region of the semiconductor substrate on an rear surface of the SOI substrate where the MOSFET is formed using a photolithography technique; and performing anisotropic etching using the mask.

11. The method for making the semiconductor device according to claim 10, wherein the anisotropic etching is RIE.

12. The method for making the semiconductor device according to claim 6, wherein the removing the supporting substrate further comprises heating the SOI substrate to a predetermined temperature.

13. The method for making the semiconductor device according to claim 6, wherein the etching the semiconductor substrate further comprises performing wet etching.
